(19) United States
(12) Patent Application Publication
(10) Pub. No.: US 2020/0098945 A1
(43) Pub. Date: Mar. 26, 2020

(54) PROCESS FOR PRODUCING A PHOTOVOLTAIC SOLAR CELL HAVING A HETEROJUNCTION AND A DIFFUSED-IN EMITTER REGION

(71) Applicant: Fraunhofer-Gesellschaft zur Förderung der angewandten Forschung E.V., Munchen (DE)

(72) Inventors: Martin Hermle, Freiburg (DE); Stefan Janz, Freiburg (DE)

(73) Assignee: Fraunhofer-Gesellschaft zur Förderung der angewandten Forschung E.V., Munchen (DE)

(21) Appl. No.: 16/578,993

(22) Filed: Sep. 23, 2019

(30) Foreign Application Priority Data
Sep. 24, 2018 (DE) 102018123397.3

(51) Int. Cl. H01L 31/18; H01L 31/0747; H01L 31/20

(52) U.S. Cl. CPC H01L 31/1804; H01L 31/202; H01L 31/1868; H01L 31/0747

(57) ABSTRACT

A process for producing a photovoltaic solar cell having at least one diffused-in diffusion region and at least one heterojunction, including (A) providing at least one semiconductor substrate having a base doping, (B) producing the heterojunction on a rear side of the semiconductor substrate, which heterojunction includes a doped, silicon-containing heterojunction layer and a dielectric tunneling layer arranged indirectly or directly between heterojunction layer and semiconductor substrate, (C) texturing the surface of the semiconductor substrate at least on a front side of the semiconductor substrate; and (D) producing the diffusion region on the front side of the semiconductor substrate by diffusing at least one diffusion dopant having a doping type opposite to the base doping into the semiconductor substrate. These steps are, with or without intervening process steps, carried out in the order A-C-B-D. The diffusion region is produced in process step D by diffusion from the gas phase at a temperature in the range from 700° C. to 1200° C. in a low-oxygen atmosphere with introduction of a doping gas mixture containing the dopant, a heat treatment at a temperature in the range from 700° C. to 1200° C. without introduction of the doping gas mixture is carried out in at least one process step D1 after process step D, with or without insertion of further process steps, in order to drive the diffusion dopant into the semiconductor substrate and in order to activate the doped heterojunction layer, and process steps D and D1 are carried out in-situ and during these the rear side of the semiconductor substrate is protected by a diffusion-inhibiting element which is not a constituent of the solar cell.

### INCORPORATION BY REFERENCE

The following documents are incorporated herein by reference as if fully set forth: German Patent Application No. 10 2018 123 397.3, filed Sep. 24, 2018.

### BACKGROUND

The invention relates to a process for producing a photovoltaic solar cell having at least one diffused-in emitter region and at least one heterojunction.

A photovoltaic solar cell is a sheet-like semiconductor component in which charge carrier pairs are produced by absorption of incident electromagnetic radiation and are subsequently separated at a pn junction, so that a potential arises between at least two electrical contact points of the solar cell and electric power can be taken off.

The pn junction can be realized by an appropriate emitter region being formed in a semiconductor substrate having a base doping by with a dopant diffusion of an emitter doping opposite to the base doping so that a pn junction is formed between emitter region and base-doped region of the semiconductor substrate.

It is likewise known that emitters can be formed by application of one or more layers to a base substrate, in particular by application of an emitter layer composed of amorphous silicon on a base substrate consisting of monocrystalline silicon. Here too, the emitter layer has a doping type opposite to the base doping (doping types are the n-doping type and the p-doping type opposite thereto), so that a pn junction is formed between emitter and base. Since the amorphous silicon layer of the emitter has a different band gap than the crystalline silicon of the base, a hetero-pn-junction is formed, so that a heteroemitter is present.

However, if base substrate and amorphous silicon layer have the same doping type but different doping concentrations, a heterojunction, in this case a “high-low junction”, is likewise formed. Such heterojunctions are used to form heterocontacts:

Different physical contact types are also known in the contacting of the semiconductor regions: Typically, a metallic contacting structure is applied directly or indirectly to the semiconductor region to be contacted. In particular, the formation of an ohmic contact and a Schottky contact is known here. MOS/MIS contacts are likewise known as specific embodiments of a heterocontact. A specific embodiment of MOS/MIS contacts is the following structure: substrate/tunnel oxide/doped poly-Si layer. Such contact types are known for semiconductors and are, for example, described in Peter Würfel, Physics of Solar Cells: From Principles to New Concepts. 2005, Weinheim: Wiley-VCH. (Heterocontact: chapter 6.6, p. 127ff; Schottky contact: chapter 6.7.1, p. 131f; MIS contact: chapter 6.7.2, p. 132) and Sze, S. M., Semiconductor devices: Physics and Technology. 1985, New York: John Wiley & sons. (MOS contact: chapter 5.4, p. 186; metal-semiconductor contact: chapter 5.1, p. 160ff.).

Heterojunctions are classically regarded as junctions between materials having different band gaps. However, heterojunctions can also be formed with arrangement of a tunnel layer between semiconductor substrate and heterojunction layer, for example as substrate/tunnel oxide/silicon-containing layer or MIS contacts as described above. The term “heterojunction” is for the purposes of the present patent application used in this comprehensive sense. The “hetero” property of the heterojunction can thus be based on a different bandgap between semiconductor substrate and heterojunction layer and/or between tunnel layer and heterojunction layer.

In this patent application, the term “heterojunction” encompasses, as mentioned above, both junctions having layers of different doping types, in particular to form heteroemitters, and also junctions between layers having the same doping types, in particular to form heterocontacts.

Analogously to the definition introduced in respect of the emitters, contacts which are not heterocontacts are for the present purposes referred to as homocontacts.

There is a need for production processes for solar cells which combine diffused doping regions with heterojunctions. This can be, for example, the combination of a hetero-pn-junction with a highly doped base region, i.e. a region of the base doping type which is more highly doped than the base doping (also referred to as “BSF” (back surface field) when arranged on the rear side and as “FSF” (front surface field) when arranged on the front side). It can likewise be the combination of a heterocontact with a homoemitter produced by diffusion of a dopant, with corresponding formation of a homo-pn-junction.

A solar cell which has diffused regions and heterojunctions is known from DE 10 2013 219 564 A1.

### SUMMARY

It is an object of the present invention to improve the previously known process in respect of cost efficiency and potential for high efficiencies of the photovoltaic solar cell produced.

This object is achieved by a process having one or more features of the invention. Advantageous embodiments are described below and in the claims.

The process of the invention for producing a photovoltaic solar cell having at least one diffused-in diffusion region and at least one heterojunction comprises the following process steps:

In a process step A, at least one semiconductor substrate having a base doping is provided. In a process step B, the heterojunction is produced on a rear side of the semiconductor substrate. The heterojunction is formed by a doped, silicon-containing heterojunction layer and a dielectric tunnel layer arranged indirectly or directly between heterojunction layer and semiconductor substrate. In a process step C, the surface of the semiconductor substrate is textured at least on a front side of the semiconductor substrate located opposite the rear side. In a process step D, the diffusion region is produced on the front side of the semiconductor substrate by diffusing in at least one diffusion dopant having a doping type opposite to the doping type of the heterojunction layer into the semiconductor substrate.

It is important that the abovementioned process steps are carried out in the order A-C-B-D. Here, the insertion of further process steps between the process steps mentioned or no further process steps being inserted are equally possible within the scope of the invention.

Furthermore, the diffusion region is produced in process step D by diffusion from the gas phase at a temperature in the range from 700° C. to 1200° C. in a low-oxygen atmosphere with introduction of a doping gas mixture containing the dopant.

After process step D, with or without insertion of further process steps, a heat treatment at a temperature in the range from 700° C. to 1200° C. without introduction of the doping gas mixture is carried out in at least one process step D1 in order to drive the diffusion dopant into the semiconductor substrate and to activate the doped heterojunction layer.

The process steps D and D1 are carried out in-situ and during these steps the rear side of the semiconductor substrate is protected by a diffusion-inhibiting element which is not a constituent of the solar cell.

The invention is based on the recognition that photovoltaic solar cells having a diffused diffusion region, in particular a diffused emitter, in particular on silicon-based solar cells, are usually limited by the recombination at the metal-semiconductor contact since the open-circuit voltage can be significantly reduced in this way. There is therefore a need to provide a process for producing a photovoltaic solar cell in which the efficiency can be increased by reducing the recombination at the metal-semiconductor contact and also by optimizing the doping profile, in particular an emitter profile. At the same time, this process should be inexpensive so that an achieved increase in the efficiency is not balanced out by increased production costs.

The process of the present invention thus offers the possibility of forming a heterocontact on the rear side by use of the heterojunction, so that the abovementioned losses in the case of the open-circuit voltage are considerably reduced. Furthermore, the usual formation of a doping glass is prevented by production of the diffusion region from the gas phase in a low-oxygen atmosphere. In contrast to conventional processes for producing a diffused-in emitter, no doping glass is thus used as dopant source, which represents an “infinite dopant source” under customary process conditions. This achieves firstly the advantage that more precise formation of the doping profile of the diffusion region, in particular an emitter profile, is possible.

The amount of the dopant available for the doping process in production of the diffusion region can be prescribed via the amount and concentration of the dopant in the doping gas mixture in the present process. In particular, the dopant can be driven in in process step D1 with an at least considerably reduced introduction, if any, of fresh dopant into the semiconductor substrate since no introduction of the doping gas mixture is carried out in process step D1. It is thus possible to produce significantly more precise desired doping profiles in order to increase the efficiency.

In addition, no etching away of a doping glass is necessary in the process of the invention since, as indicated above, the formation of such a glass is avoided as a result of the low-oxygen atmosphere. However, this continues to make it possible to carry out at least the process steps D and D1 in-situ, with the rear side of the semiconductor substrate (and thus the heterojunction) being protected by a diffusion-inhibiting element which is not a constituent of the solar cell. The production of a highly efficient solar cell structure in an uncomplicated and thus inexpensive way is thus made possible, with it not being necessary, in particular for process steps D and D1, to apply a diffusion barrier layer to the rear side of the solar cell and also not to take the semiconductor substrate from a process chamber between these process steps.

The process of the invention is also made inexpensive by the diffusion dopant being driven into the semiconductor substrate and the doped heterojunction layer being activated at the same time in process step D1.

Correspondingly, texturing of the surface as per process step C is, in contrast to the typical procedure in previously known processes, carried out in the process of the invention before production of the heterojunction in process step B.

The process of the invention thus allows production of a solar cell structure for very high efficiencies without additional, costly process steps being necessary or these being balanced out by saving of additional steps compared to previously known processes.

In the present invention, a diffusion region is thus formed directly from the gas phase without a doping glass being formed and modification of the doping process from the gas phase by changing the doping gas mixture, in particular the dopant concentration in the doping gas mixture, is made possible thereby and also the dopant is driven in without introduction of doping gas mixture and the doped heterojunction layer is activated simultaneously during the driving-in.

The advantage that, in particular, the diffusion region is diffused in without etching away of a doping glass being necessary is thus obtained. As a result of the use of a diffusion-inhibiting element which is not a constituent of the solar cell, no protective layer is necessary on the rear side of the solar cell during production of the diffusion region. The additional degrees of freedom in the production of the diffusion region due to the altering of the doping gas mixture and the driving-in without introduction of doping gas mixture enables an optimal doping profile of the diffusion region to be achieved. Optimal activation can be carried out by activation of the heterojunction layer in process step D1 without undesirable doping of the diffusion region occurring.

The process of the invention thus makes possible a very simple and elegant process sequence which, in contrast to typical previously known processes, does not require any rear-side protective layer during diffusion of the diffusion region, requires no high-concentration hydrofluoric acid for removing a doping glass and at the same time makes an optimal doping profile and optimal activation of the heterojunction layer possible.

The production of the diffusion region is thus preferably effected without formation of a glass layer containing the diffusion dopant, so that removal of the glass layer is not necessary either.

As stated above, the rear side of the semiconductor substrate is protected by a diffusion-inhibiting element which is not a constituent of the solar cell during process steps D and D1. Advantageously, no diffusion-inhibiting layer is therefore arranged on the rear side of the solar cell and preferably on the front side of the solar cell during process steps D and D1. This makes the process simpler and thus cheaper.

The tunnel layer produced in process step B is configured as dielectric tunnel layer to form a heterojunction known per se. Studies show that charge transport over such a heterojunction is achieved by the mechanism of tunneling. Likewise, it appears from the present stage of research that charge transport is possible through a plurality of small openings, known as “pinholes”. For the purposes of the present patent application, the dielectric tunnel layer is thus any dielectric layer which is suitable for forming a heterojunction.

The dielectric tunnel layer is advantageously produced with a thickness of greater than 0.5 nm, in particular in the range from 1 nm to 5 nm, in process step B. Furthermore, it is advantageous that, in process step D and/or in process step D1, at least partial crystallization of the doped, silicon-containing heterojunction layer occurs, and the passivation quality of the tunnel layer is improved by heating to a temperature above 850° C., preferably for a time of at least 5 minutes. This promotes the formation of a heterojunction having a high electronic quality.

In the case of relatively thick tunneling layers (>2 nm) in which charge transport by tunneling becomes improbable, a relatively high temperature above 950° C. can lead to partial break-up of the tunneling layer and thus make charge transport through the “pinholes” possible for the first time. For this reason, higher process temperatures can also be used in D for thicker layers in B. The layer thickness in B and the process temperatures in D can therefore be matched to one another so that optimal charge transport can occur and a very good emitter can be formed. At process temperatures up to 900° C., the layer thickness of the tunneling layer is preferably less than or equal to 1.5 nm; in the process temperature range 900-1100° C., the layer thickness of the tunneling layer is preferably in the range from 1.5 nm to 3 nm.

The doping gas mixture preferably contains the dopant and hydrogen. In particular, it is advantageous for the doping gas mixture to consist of dopant and hydrogen. This makes an efficient diffusion operation to form the diffusion region possible and at the same time prevents formation of a doping glass.

Dopants are preferably materials from main group III or V, particularly preferably boron or phosphorus.

The semiconductor substrate can be configured as a semiconductor substrate known per se, particularly preferably as silicon layer, in particular silicon wafer. The semiconductor substrate being made of germanium is likewise within the scope of the invention.

In an advantageous embodiment, at least the process step D is carried out in a process atmosphere containing less than 5% of oxygen, in particular less than 1% of oxygen, preferably in an oxygen-free process atmosphere, in order to prevent the formation of doping glass. In a further preferred embodiment, oxygen is reintroduced into the process atmosphere in process step D1, since this results in formation of a passivating oxide layer on the diffusion region.

As indicated above, the process of the invention not only makes it possible to drive in the dopant to form the diffusion region with only slight additional introduction, if any, of dopant in process step D1. Furthermore, in an advantageous embodiment the introduction of the doping gas mixture is altered, in particular controlled as a function of a prescribed gas inflow profile, during process step D. In this way, an optimal doping profile of the diffusion region can be produced in a targeted manner. In particular, it is thus advantageous to regulate a prescribed dopant concentration in the doping gas mixture during process step D as a function of a prescribed course over time of the dopant concentration in the doping gas mixture.

To achieve a desired doping profile, it can be advantageous, in a preferred embodiment, to carry out the process steps D and D1 alternately a number of times. Thus, formation of the diffusion region with introduction of the doping gas mixture (process step D) takes place, followed by driving-in without introduction of doping gas mixture (process step D1), again diffusion from the gas phase with the introduction of doping gas mixture (D) and finally again driving-in without introduction of doping gas mixture (D1). Likewise, adding further sequences of process steps D and D1 is within the scope of the invention. This advantageous embodiment is particularly advantageous for emitter doping profiles which have low recombination and nevertheless a high surface concentration, so that they can be contacted readily.

The process of the invention offers the possibility of configuring the formation of the diffusion region, in particular of a diffusion region functioning as emitter, as advantageous doping process:

In an advantageous embodiment of the process of the invention, process step D is configured as rapid vapor phase direct doping (RVD). This gives the additional advantage that the process sequence can be particularly short and thus inexpensive as a result of rapid heating and cooling of the Si wafer. The RVD process is known per se and is described, for example, in Lindekugel et al, EMITTERS GROWN BY RAPID VAPOUR-PHASE DIRECT DOPING FOR HIGH EFFICIENCY SOLAR CELL, 31st European PV Solar Energy Conference and Exhibition, Sep. 14-18, 2015, Hamburg, Germany. Process step D is therefore preferably carried out at a process temperature in the range from 750° C. to 1100° C.

The heat treatment in process step D1 is preferably carried out for at least 1 minute, in particular for at least 10 minutes. This promotes full activation of the heterojunction. Particularly when process step D is configured as RVD process, a heat treatment in the range from 5 minutes to 30 minutes is advantageous.

As indicated above, the process of the invention provides, in particular, high degrees of freedom and allows precise formation of a desired diffusion profile, in particular emitter doping profile, and the matching rear side structure. The formation of the diffusion region therefore advantageously occurs without any diffusion from the solid phase of a doping layer. Preference is therefore given to no layer from which a significant amount of dopant penetrates into the semiconductor layer and thus influences the diffusion profile during production of the diffusion region before and during the formation of the diffusion region, in particular as emitter. This ensures that precise formation of the diffusion doping profile occurs according to what is prescribed.

The heterojunction layer is preferably applied as amorphous, silicon-containing layer. In process step D and/or in process step D1, the heterojunction layer is preferably at least partly, particularly preferably completely, converted into a polycrystalline silicon layer. The activation of the heterojunction is preferably carried out in a manner known per se, in particular by heating at least the semiconductor substrate in the region of the heterojunction layer to at least 600° C., preferably for a time of at least 10 minutes. This corresponds to parameters known per se for activation of such a heterojunction.

The dielectric tunneling layer can be doped with a dopant or be intrinsic (undoped).

The diffusion region is preferably formed exclusively on the front side of the solar cell. The diffusion region preferably covers at least 50%, preferably at least 90%, particularly preferably at least 99%, of the front side of the semiconductor substrate.

It is particularly advantageous for the diffusion region to be configured so as to cover the entire front side.

In process steps D and D1, the rear side of the semiconductor substrate is protected by a diffusion-inhibiting element which is not a constituent of the solar cell. This can be effected in a simple manner by, in an advantageous embodiment, the semiconductor substrate being placed on a support substrate which is present in a process chamber. In this way, the process steps D and D1 can be carried out in-situ in a simple manner, with rear-side diffusion being avoided or at least occurring at most only slightly at the same time.

The diffusion-inhibiting element can be configured as substrate holder made of ceramic, fused silica, graphite, silicon carbide or silicon as plate or block.

In a further preferred embodiment, hydrogen is introduced into the heterojunction layer and/or at the interface between tunneling layer and semiconductor substrate. This improves the electrical quality, in particular by further lowering of the surface recombination rate.

One method for introducing hydrogen into the heterojunction layer and/or at the interface between tunneling layer and semiconductor substrate is the use of RPHP, as described, for example, in S. Lindekugel, et al., “Plasma hydrogen passivation for crystalline silicon thin-films,” in Proceedings of the 23^{rd} European Photovoltaic Solar Energy Conference, Valencia, Spain, 2008, pp. 2232-5.

As an alternative, the hydrogen can be introduced by applying a hydrogen-containing layer indirectly or preferably directly to the heterojunction layer. In this case, inward diffusion of hydrogen is brought about by the process heat on application of the layer. Advantageously, hydrogen continues to be diffused in by additional hydrogen subsequently being introduced by heating, preferably to at least 350° C.

In a preferred embodiment, the abovementioned hydrogen-containing layer is configured as microcrystalline silicon layer, in particular as hydrogenized microcrystalline silicon carbide layer (μc-Siₓ-C₁₋ₓ:H). This gives the advantage that the layer is more conductive and more optically transparent than, for example, an a-Si:H layer. In particular, a μc-Siₓ-C₁₋ₓ layer can advantageously serve as transparent contact and thus replace conductive transparent electrodes, for example TCO layers, that are known per se.

The hydrogen-containing layer can likewise be configured as silicon nitride layer, in particular hydrogenized silicon nitride layer. Here, heating is preferably carried out to a temperature in the range from 700° C. to 900° C., but merely for a time of a few seconds, in particular from 1 second to 30 seconds, preferably from 1 second to 15 seconds. In this way, hydrogen is diffused in in a particularly efficient way in a process step which is not time-consuming. Due to the brief exposure to heat, diffusion of dopant is avoided or at least reduced.

In a further advantageous embodiment, a doping gas mixture containing hydrogen is used in process step D in order to introduce hydrogen into the heterojunction layer and/or at the interface between tunneling layer and semiconductor substrate. This gives the advantage that hydrogen is introduced in a simple, inexpensive way. In particular, it is advantageous for the doping gas mixture to contain at least 80%, preferably at least 90%, in particular at least 98%, of hydrogen. Preference is given to the dopant being diluted in hydrogen gas.

The above-described use of a doping gas mixture containing hydrogen has the further advantage that later introduction of hydrogen is no longer necessary. For this reason, a subsequent introduction of hydrogen into the heterojunction layer and/or at the interface between tunneling layer and semiconductor substrate is advantageously not carried out, in particular preference is given to not carrying out any RPHP step.

In a further preferred embodiment, a metallic contacting layer is applied indirectly or preferably directly to the heterojunction layer on the side facing away from the semiconductor substrate. It is particularly advantageous here to introduce hydrogen into the heterojunction layer beforehand in the manner described above and subsequently apply the metallic contacting layer.

A solar cell structure having a diffused diffusion region and a rear-side heterojunction layer is thus produced by the process of the invention.

The semiconductor substrate is preferably doped in regions apart from emitter regions with a base doping type, preferably an n doping.

In an advantageous embodiment, the heterojunction layer is likewise doped with the base doping type. The emitter is formed by the diffusion region and is accordingly doped with an emitter doping type opposite to the base doping type, preferably with a p doping.

In a further advantageous embodiment, the emitter is formed by the heterojunction layer, in particular heteroemitter, and has a doping type opposite to the base doping type. In this embodiment, the diffusion region has a doping of the base doping type. The diffusion region is in this case preferably configured as a layer which reduces the effective recombination on the side of the diffusion region, in particular as an FSF (front surface field).

### BRIEF DESCRIPTION OF THE DRAWINGS

Further advantageous features and embodiments are explained below with the aid of a working example and the figures.

FIGS. 1 to 5 show various stages of a working example of a process according to the invention.

### DETAILED DESCRIPTION

In the figures, identical reference symbols designate identical or equivalent elements.

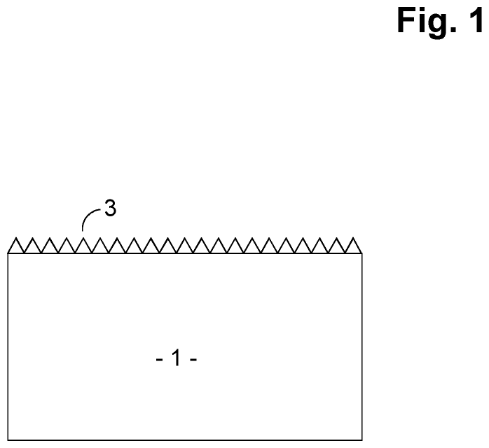

In the working example of the process of the invention, a semiconductor substrate 1 configured as silicon wafer is provided in a process step A. The semiconductor substrate has n-doping using phosphorus in a concentration of 1×10¹⁵ cm⁻³. In a process step C, texturing 3 was formed on the front side (shown at top in FIGS. 1 to 5). The semiconductor substrate 1 is configured as monocrystalline silicon substrate, so that a pyramid structure (known as “random pyramids”) can be formed on the front side in a manner known per se by one-sided etching. In the present case, KOH was used as etching medium for producing the pyramid structure.

This pyramid structure leads to multiple reflections and oblique angles of incidence, so that the total absorption is increased in the case of light incident on the front side, especially in the case of long-wavelength radiation.

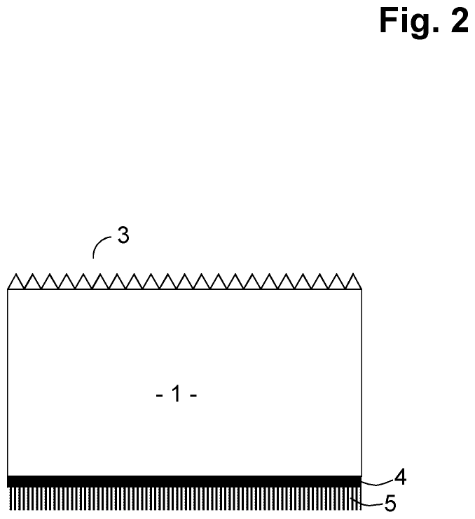

In a process step B, a dielectric tunneling layer 4 configured as silicon dioxide layer and also a heterojunction layer 5 configured as silicon or silicon carbide (SiₓC₁₋ₓ) layer are applied by wet-chemical oxidation on a rear side of the semiconductor substrate 1 which is opposite the front side. The tunneling layer 4 is thus arranged directly between heterojunction layer 5 and semiconductor substrate 1. This situation is shown in FIG. 2.

The tunneling layer 4 can likewise be applied by one of the processes PECVD, LPCVD, HPCVD, thermal oxidation, atomic layer deposition or dry oxidation by UV radiators. The silicon-containing layers (Si, SiₓC₁₋ₓ) SiC layer can likewise be applied by one of the processes PECVD (plasma enhanced chemical vapor deposition), APCVD (atmospheric pressure chemical vapor deposition), LPCVD (low pressure chemical vapor deposition), HW-CVD (hotwire chemical vapor deposition) or sputtering.

In a process step D, a diffusion region is formed as emitter region 2 on the front side of the semiconductor substrate 1, and this completely covers the front side. The emitter region 2 is configured as p-doped emitter by the doping of the semiconductor substrate 1 with the dopant boron in the region of the front side.

To form the emitter region 2, the semiconductor substrate 1 is placed with the rear side down on a diffusion-inhibiting element 8 configured as ceramic support and introduced into a process chamber 7. A virtually oxygen-free atmosphere is then produced in the process chamber 7 by feeding hydrogen and boron as doping gas mixture into the process chamber 7, and heating at a temperature of 1000° C. is carried out for a time of 30 minutes. Inward diffusion of the dopant boron on the front side of the semiconductor substrate 1 is achieved in this way. The rear side, on the other hand, is protected by the diffusion-inhibiting element 8, so that no or at most slight penetration of boron occurs here.

Due to the oxygen-free atmosphere, no glass layer is formed in this inward diffusion of boron from the gas phase.

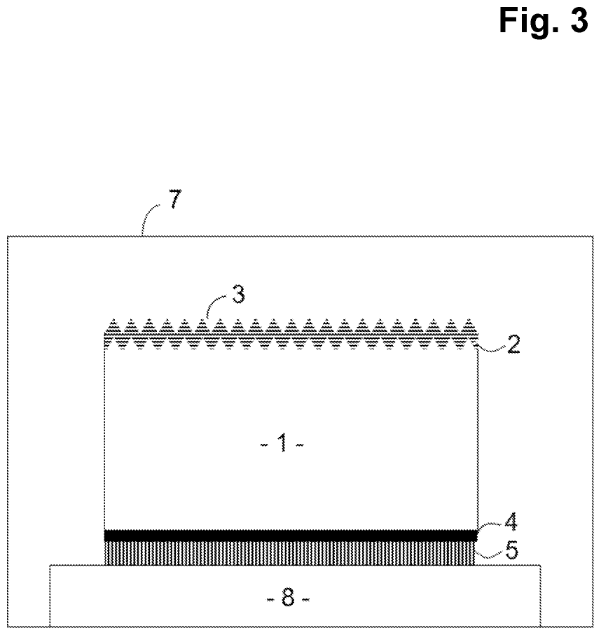

This is shown in FIG. 3.

A heat treatment at a temperature in the region of 1000° C. for 1 minute without introduction of the doping gas mixture is subsequently carried out in-situ, i.e. without the semiconductor substrate being taken from the process chamber 7, in a process step 1) 1. In this process step D1, no or at most only slight inward diffusion of boron from the gas phase thus occurs. A driving-in of the dopant already present in the semiconductor substrate 1 effectively occurs during process step D1.

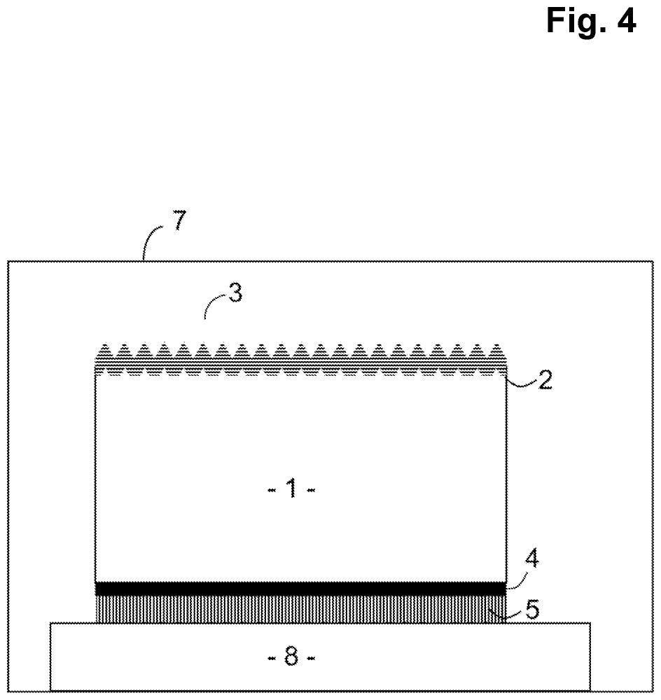

This is shown in FIG. 4.

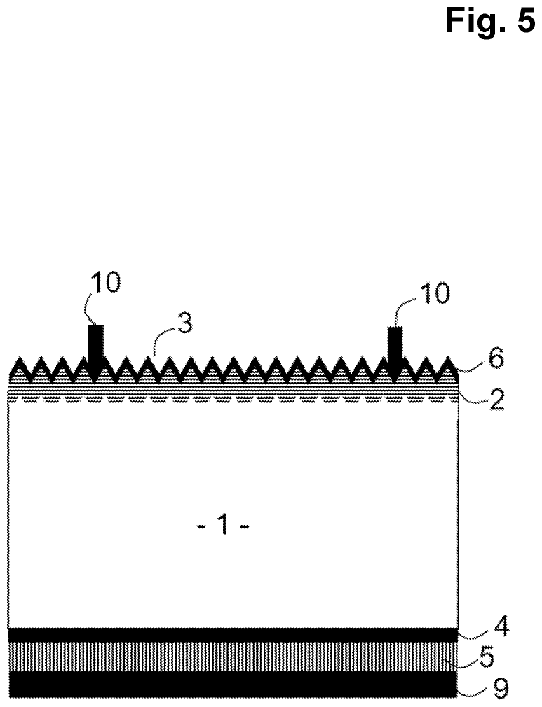

A metallic rear side contact 9 is subsequently applied over the full area of the rear side. On the front side, an antireflection layer 6 configured as silicon nitride layer having a thickness of 80 nm is applied in order to increase the light absorption further. In a modification of the working example described, a passivating layer, preferably an oxide layer, in particular an Al₂O₃ layer, preferably having a thickness in the range from 5 to 20 nm, is arranged between antireflection layer and semiconductor substrate. Furthermore, a metallization grid which penetrates through the antireflection layer 6 and thus electrically contacts the emitter region 2 is applied as metallic front side contact 10 on the front side in a manner known per se. This is shown in FIG. 5.

In a modification of the working example described, the diffusion region is configured as “front surface field” (FSF) having a doping of the base doping type, in particular by boron, and the heterojunction layer as heteroemitter is correspondingly doped with a doping type opposite from the base doping type, in particular doping using phosphorus.

In the following table, preferred parameter ranges and, shown underlined the parameters prevailing in this working example and optionally the production methods for the individual layers are reported: as described above, doping of the diffusion region is, in a preferred embodiment, effected as p type (emitter) and the doping of the base and also the heterojunction layer is effected as n type. In a further preferred embodiment, doping of the diffusion region and the base is effected as p type and the doping of the heterojunction layer is effected as n type (emitter).

| Layer/region | | | |
|---|---|---|---|
| (reference symbols) | Material | Thickness | Doping [cm⁻³] |
| Antireflection | SiN, SiO₂ | 50 nm-200 nm; | — |
| layer (6) | Al₂O₃/SiNₓ (1- | 10/65 nm | |
| | 20 nm/65-85 nm) | | |
| Homo-diffusion | Si wafer | 0.2-1.5 μm | p type/n type |
| region: (2) | (diffused-in) | 0.3 μm | (boron/ |
| | | | phosphorus) |
| Semiconductor | Si wafer | 50 μm-300 μm; | p type/n type |
| substrate (1) (base) | (base doping) | 200 μm | (boron/ |
| | | | phosphorus |
| | | | 10¹⁴-3 10¹⁶ |
| | | | 10¹⁵) |
| Dielectric | SiO₂ | 0.5 nm-3 nm: | — |
| tunneling layer (4) | | 1.0 nm | |
| Heterojunction | Si, SiₓC₁₋ₓ | 5 nm-100 nm: | p type/n type |
| layer (5) | SiₓO₁₋ₓ | 20 nm | (boron/ |
| | | | phosphorus |
| | | | 10¹⁶-10²¹ |
| | | | 10¹⁹) |
| Rear-side | Ag, Al, TCO/Ag | 100 nm-5 μm | — |
| metallization: Rear- | TCO/AI, | 1 μm | |
| side contact (9) | TCO/Cu, TCO/Ni | | |
| Front-side | AgAl paste, Ag | Height: | |
| metallization (10) | paste, NiCu | 1 μm-50 μm | |
| | | 10 μm; | |
| | | Width: | |
| | | 5 μm-100 μm | |
| | | 30 μm | |

1. A process for producing a photovoltaic solar cell having at least one diffused-in diffusion region (2) and at least one heterojunction, the process comprising the steps:
A providing at least one semiconductor substrate having a base doping;
B producing the heterojunction on a rear side of the semiconductor substrate, said heterojunction comprising a doped, silicon-containing heterojunction layer (5) and a dielectric tunneling layer arranged indirectly or directly between heterojunction layer (5) and a semiconductor substrate (1);
C texturing a surface of the semiconductor substrate at least on a front side of the semiconductor substrate which is opposite a rear side;
D producing a diffusion region on the front side of the semiconductor substrate by diffusing at least one dopant having a doping type which is opposite to a doping type of the heterojunction layer into the semiconductor substrate (1);
wherein the abovementioned process steps are carried out in the order A-C-B-D, with or without insertion of additional process steps, wherein the diffusion region (2) is produced in process step D by diffusing from a gas phase at a temperature in the range from 700° C. to 1200° C. in a low-oxygen atmosphere with introduction of a doping gas mixture containing the dopant; D1 carrying out a heat treatment at a temperature in the range from 700° C. to 1200° C. without introduction of the doping gas mixture after process step D, with or without insertion of further process steps, in order to drive the diffusion dopant into the semiconductor substrate (1) and in order to activate the doped heterojunction layer (5), and
wherein process steps D and D1 are carried out in-situ and during said processing steps D and D1, the rear side of the semiconductor substrate is protected by a diffusion-inhibiting element (8) which is not a constituent of the solar cell.

2. The process as claimed in claim 1, wherein production of the diffusion region is effected without formation of a glass layer containing the diffusion dopant.

3. The process as claimed in claim 1, wherein no diffusion-inhibiting layer is arranged on the rear side of the solar cell in process steps D and D1.

4. The process as claimed in claim 1, wherein no diffusion-inhibiting layer is arranged on the front side of the solar cell in process steps D and D1.

5. The process as claimed in claim 1, wherein the dielectric tunneling layer (4) in process step B has a thickness of greater than 0.5, and the process further comprises effecting a conversion of the heterojunction layer from an amorphous state into an at least partially polymorphous state in at least one of the process steps D or D1, with a tunneling oxide being such that a low contact resistance arises.

6. The process as claimed in claim 1, wherein the doping gas mixture contains the dopant and hydrogen.

7. The process as claimed in claim 1, further comprising carrying out at least the process step D in a process atmosphere containing less than 5% of oxygen, and introducing oxygen into the process atmosphere again in process step D1 in order to form an oxide layer.

8. The process as claimed in claim 1, further comprising altering the introduction of the doping gas mixture during process step D as a function of a prescribed gas inflow profile.

9. The process as claimed in claim 1, wherein process steps D and D1 are carried out alternately a plurality of times.

10. The process as claimed in claim 1, wherein process step D comprises rapid vapor-phase direct doping (RVD).

11. The process as claimed in claim 1, further comprising carrying out the heat treatment in process step D1 for at least 1 minute.

12. The process as claimed in claim 1, wherein no diffusion from the solid phase of a doping layer occurs in order to form the diffusion region.

13. The process as claimed in claim 1, wherein the heterojunction layer (5) is applied as amorphous, silicon-containing layer and is converted at least partially into a polycrystalline silicon layer in at least one of process step D or D1.

14. The process as claimed in claim 1, wherein the diffusion region (2) covers at least 90% of the front side,

15. The process as claimed in claim 1, wherein the diffusion region is configured as emitter or as front surface field.

16. The process as claimed in claim 1, wherein a doping gas mixture containing hydrogen is used in process step D.

17. The process as claimed in claim 16, wherein the doping gas mixture contains at least 80% hydrogen.
